(19) United States
(12) Patent Application Publication
(10) Pub. No.: US 2007/0272924 A1
(43) Pub. Date: Nov. 29, 2007

(54) INTEGRATED CIRCUIT (IC) TESTING DEVICE WITH CONDUCTION INTERFACE

(75) Inventor: Chu Yung-Sing, Taoyuan County (TW)

Correspondence Address: LOWE HAUPTMAN HAM & BERNER, LLP, 1700 DIAGONAL ROAD, SUITE 300, ALEXANDRIA, VA, 22314, US

(73) Assignee: TANGERINE SYSTEM CO., LTD., Taoyuan County (TW)

(21) Appl. No.: 11/739,258

(22) Filed: Apr. 24, 2007

(30) Foreign Application Priority Data
May 29, 2006 (TW) 095209283

(51) Int. Cl. H01L 23/58

(52) U.S. Cl. 257/48

(57) ABSTRACT

An IC testing device with conduction interface comprising an electrical circuit board having a test circuit; an insulation pad set on the circuit board; and a pressing block provided on the insulation pad for depressing the pins of the IC. While the conduction interface comprises a plurality of contactors provided in the insulation pad for electrically connecting with the pins of the IC and the electrical circuit on the circuit board. The insulation pad is also provided with an accommodation cavity in communication with outside and for accommodating the contactors. In addition, the conduction interface further comprises an elastic axle provided in the accommodation cavity whereas each of the contactors has a receptacle to hold the elastic axle; a conducting lead which is extended and protruded out of the insulation pad in contact with the pins of the IC; and a contact surface for electrically contacting with the electrical test circuit of the circuit board. By using the deformational character of the elastic axle when a force is applied at one said thereof, the displace or rotational space for contactor is provided, and the abrasive damage to the circuit board which may lead to degrade the conductivity of the electrical circuit on the circuit board is prevented.

### BACKGROUND OF THE INVENTION

1. Field of the Invention

The present invention relates to an integrated testing device, and in particular, to an integrated testing having conduction interface for integrated circuit to electrically conduct the pins of integrated circuit and the electrical circuit on the circuit board. The conduction interface utilizes a deformable elastic axle to elastically press contactors so as to avoid abrading the circuit board, when the contactors are pressed to generate a displacement.

2. Description of the Related Art

After being packaged, an integrated circuit board has to be processed with testing the conducting condition of its pins by a testing device. FIG. 1 is a schematic view of a conventional testing device 1 for carrying out the conductivity test for an IC. The testing device 1 comprises a circuit board 11 on which a testing circuit (not shown) being entrained; an insulation platform 12 formed of an insulation material being set on the circuit board 11; and a pressing block 13 located on the platform 12 to press a plurality of pins 21 (only one of them is shown) of IC 2. Two axles 14 and a plurality of conducting strips 15 are provided in the platform 12, and, a groove 121 which communicates with outside and has a longitudinal trench and two transverse trenches extending respectively from two ends of the longitudinal trench towards opposite direction each other is also formed in the platform 12, and each of the transverse trench has a recessed region 122 for holding one of said axles 14. Each of the conducting strips 15 has a center section 151 and two terminals 152, 152 warpedly extending therefrom respectively in opposite direction. One of the axles 14 is settled at the lower edge of the joint portion between the center section 151 and the terminal 152, while the other axle 14 is settled at the upper edge of the joint portion between the center section 151 and the terminal 152′. The conducting strip 15 is inclined and the joint portion of the terminal 152 is emerged out of the platform 12 so as to contact the pin 21 of the IC 2. The terminal 152′ of said conducting strip 15 is electrically contact in point with a conducting plate 111. Such that the testing circuit on the circuit board 11 can be used to test whether all of the pins 21 of the IC are able to operate properly through conducting strips 15.

In carrying out the test, when the pressing block 13 forcibly depresses the pin 21 of the IC 2 according to the arrow direction shown in FIG. 1, the upper edge of the joint between the terminal 152 and center section 151 of the conducting strip 15 shall be indirectly depressed. Since the two terminals of said conducting strip 15 is respectively forcibly supported by the axle 14 in its upper and lower directions, the conducting strip 15 has to overcome the static contact friction before displacement. Thus, the surface of the circuit board 11 will be abraded by the aforesaid friction after long time operation. In case the abrasion of the surface of the circuit board 11 becomes too severe, the test quality and accuracy for the conductivity of the pin 21 will be greatly degraded.

### SUMMARY OF THE INVENTION

Accordingly, it is the main object of the present invention to provide an IC testing device with conduction interface by which the abrasion of the circuit board during the test can be prevented and it can ensure not to affect the conductivity of the testing circuit.

To achieve the above mentioned object, the IC testing device with conduction interface according to the present invention comprises an electrical circuit board having a test circuit; an insulation pad set on the circuit board; and a pressing block provided on the insulation pad for depressing the pins of the IC. While the conduction interface comprises a plurality of contactors provided in the insulation pad for electrically connecting with the pins of the IC and the electrical circuit on the circuit board. The insulation pad is also provided with an accommodation cavity in communication with outside and for accommodating the contactors. In addition, the conduction interface further comprises an elastic axle provided in the accommodation cavity whereas each of the contactors has a receptacle to hold the elastic axle; a conducting lead which is extended and protruded out of the insulation pad in contact with the pins of the IC; and a contact surface for electrically contacting with the electrical test circuit of the circuit board.

The aforesaid elastic axle is formed of an elastic material having a deformational character when a force is applied at one side thereof so as to mitigate the stress of the applied force to the contactor by providing a space for displacement thereby minimizing the frictional fore between the contactor and the circuit board, thus preventing the abrasive damage to the circuit board which may lead to degrade the conductivity of the electrical circuit on the circuit board.

### BRIEF DESCRIPTION OF THE DRAWINGS

FIG. 1 is a schematic cross sectional view of a conventional IC testing device;

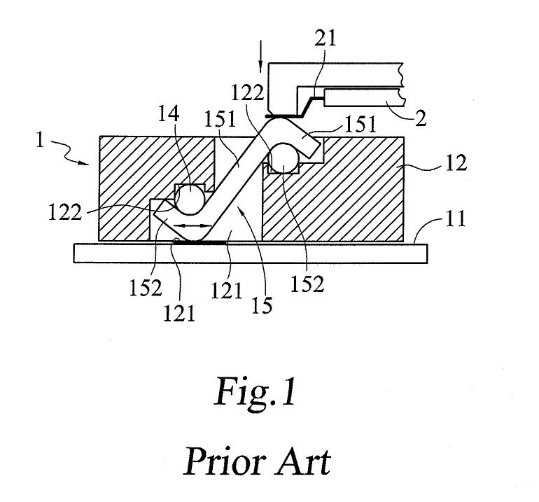

FIG. 2 is a schematic cross sectional view of the IC testing device with conduction interface according to an embodiment of the present invention;

FIG. 3 is an illustrative view demonstrating the operation of the IC testing device shown in FIG. 2;

FIG. 4 is a schematic cross sectional view in a first embodiment;

FIG. 5 is a illustrative view demonstrating the operation of the IC testing device shown in FIG. 4;

FIG. 6 is a schematic cross sectional view in a second embodiment.

### DETAILED DESCRIPTION OF PREFERRED EMBODIMENTS

The above object and other advantages of the present invention will become more apparent by describing in detail the preferred embodiments of the present invention with reference to the attached drawings.

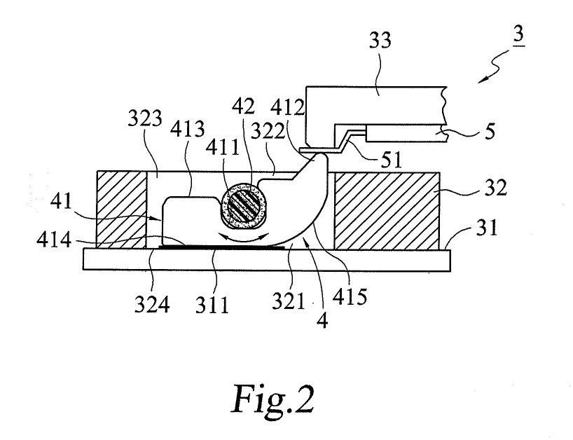

Referring to FIG. 2, the IC testing device 3 of the present invention comprises an electrical circuit board 31 having a test circuit (not shown); an insulation pad 32 set on the circuit board 31; a pressing block 33 provided on the insulation pad 32; and a conduction interface 4. A plurality of contact points 311 are provided on the circuit board 31.

The insulation pad 32 is provided with an accommodation cavity 321 in it with two openings 322, 323 formed on the top surface thereof, while the bottom surface thereof has a via hole 324. Said openings 322, 323 and via hole 324 in the accommodation cavity 321 are communicative.

The conduction interface 4 comprises a plurality of contactors 41 provided in the accommodation cavity 321 of the insulation pad 32, and an elastic axle 42 contained in the accommodation cavity 321. The axle 42, which is configured cylindrical, is made of rubber, plastics, elastic materials or other synthetic materials, and the outer surface of the axle 42 may be covered by at least one layer of elastic substance. The axle 42 is transversely inserted into the accommodation cavity 321 of the insulation pad 32. Each of the contactors 41 has a receptacle 411 to hold the elastic axle 42. A conducting lead 412 is extended upwards from one side of the receptacle 411 and passes through the opening 322 of the insulation pad 32. A contact surface 414 is located under a flat plane 413 to be in contact with the contact points 311 on the circuit board 31. Furthermore, an arcuate contact portion 415 is connected between the conducting lead 412 and the contact surface 414.

In testing the pins 51 of IC 5, the IC 5 is put on the insulation pad 32 to lay the pins 51 onto the upper end of the conducting lead 412 of the contactor 41. When the pressing block 33 is pressed downward so as to make the pins 51 of the IC 5 to press the conducting lead 412 of the contactor 41 beneath. The IC 5 is then allowed to be electrically connected with the testing circuit on the circuit board 31 via the contactors 41 to form an electrical circuit for testing the conductivity of the pins 51.

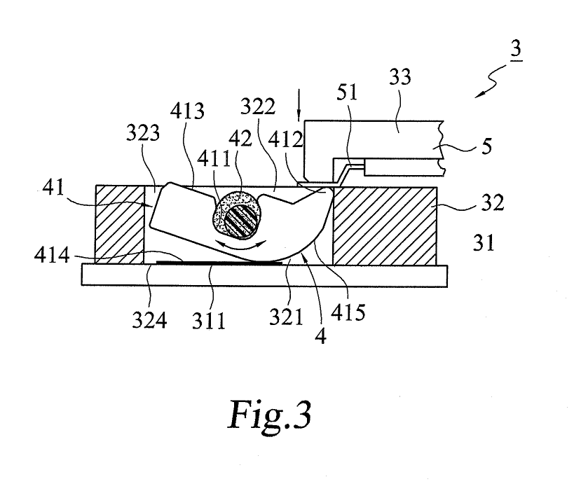

Referring to FIG. 3, it should be specially pointed out that when the pressing block 33 presses down the conducting lead 412 by way of the pin 51 of the IC 5, the contactor 41 is then able to swing and displace about the center of axis of the elastic axle 42. Since the surface of the axle 42 is elastically deformable, the motion of the contactor 41 does not have to overcome the static frictional resistance coming from the circuit board 31. As a result, the circuit board 31 is free from abrasion, and poor electrical contact between the IC 5 and the electrical circuit of the circuit board 31 by way of the contactors 41 is prevented

Said elastic axle 42 can be a silicon elastomer, an elastic fiber, a thermoplastic elastomer or a synthetic elastomer. Its outer surface can be covered by at least one layer of elastic material.

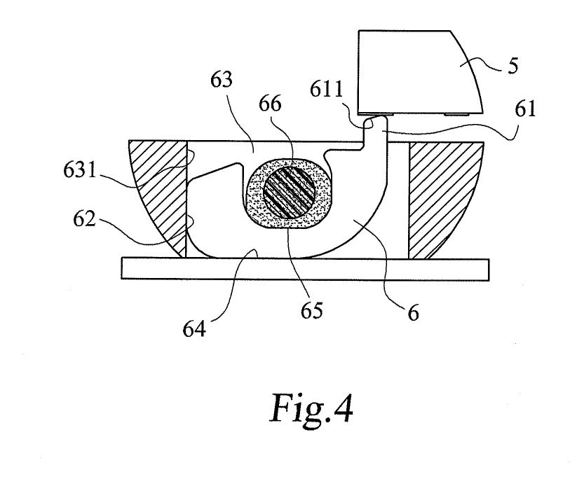

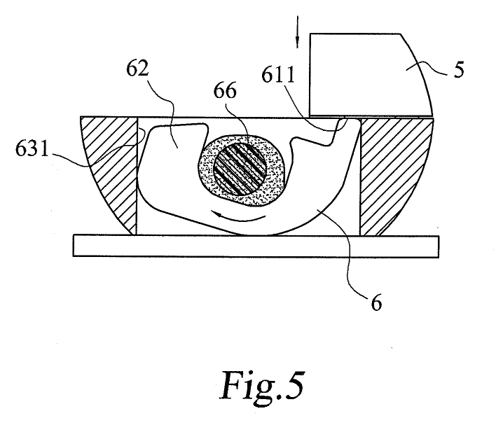

Referring to FIG. 4, in another embodiment of the present invention, the contactor 6 can be formed as to have a stub 61 at the portion in contact with the pin 51 of the IC 5. The stub 61 has a slanted top surface 611 which helps the pins 11 of the IC 5 be forcibly in surface contact with the stub 61 when the IC 5 goes down to make the contactors swing and displace. The follower end 62 of the contactor 6 is pressed against the side wall of the accommodation cavity 63 when the contactor 6 is not yet pressed downward. The following end of the contactor 6 is formed into an arcuate surface 64 and holds the elastic axle 66 with a U shaped receptacle 65. As soon as the contactor 6 is pressed down, it is able to swing in the manner shown as FIG. 5 due to elastic deformation of side surface of the axle 66 under the barrier function of the side wall 631, on the other hand, keeping slide contact with the circuit board 67 so as to avoid damaging it by abrasion.

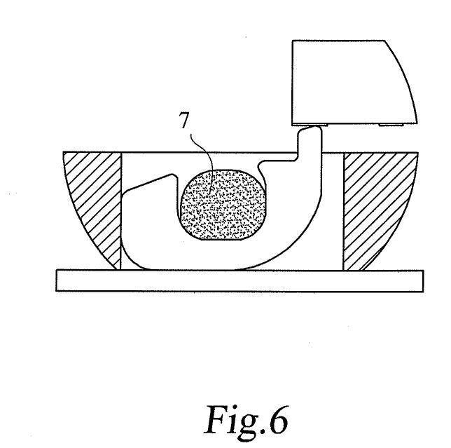

Referring to FIG. 6, in the second embodiment of the present invention, the elastic axle 7 is entirely formed of an elastic material instead of being covered with an elastic layer on the surface of axle.

The advantage of the present invention lies in fact that it has an elaborately designed elastic axle to elastically swing and displace so as to mitigate the stress coming from the contactor when being pressed down thereby protecting the abrasion of the circuit board yet still being able to maintain perfect contact.

Although the present invention has been described with a certain degree of particularity, the present disclosure has been made by way of example and changes in details of structure may be made without departing from the spirit thereof.

What is claimed is:

1. An integrated circuit (IC) testing device with conduction interface comprising:
an electrical circuit board having a test circuit;
an insulation pad set on said circuit board, wherein said insulation pad is provided with a U shaped accommodation cavity in communication with outside, and two openings formed on the top surface of the insulation pad, while a via hole is formed on its bottom surface, said two openings and said via hole are communicative in said accommodation cavity of said insulation pad;
an axle transversely inserted in said accommodation cavity of said insulation pad;
a plurality of contactors provided in said accommodation cavity of said insulation pad, each of said conductors at least has one receptacle for holding said axle, a conducting lead of said contactor is extended and protruded out of said insulation pad with a contact surface electrically in contact with the electrical test circuit of said circuit board, and an arcuate contact portion is formed between said conducting lead and said contact surface; and,
a pressing block provided on said insulation pad to oppress said IC to bring its pin forcibly in contact with said conducting lead of said contactor such that said contact surface being substantially in contact with the test circuit on said circuit board;
wherein, said axle made of elastic substance is deformable at its side surface such that when the contactor is being forcibly in contact with said circuit board, said contact surface of said contactor is able to swing and make a displacement.

2. The IC testing device as claimed in claim 1, wherein said conducting lead of said contactor is formed into a stub having a slanted top surface such that said stub can be in surface contact with said pin of said IC when said contactor swings and displaces after being pressed.

3. The IC testing device as claimed in claim 1, wherein said contactor has a follower end, and said accommodation cavity of said insulation pad has a side wall facing to said follower end of said contactor, before being oppressed, said follower end is in contact with said side wall, and after being oppressed, said contactor is able to swing and make a sliding displacement due to elastic deformation of said axle under the barrier function of the side wall of said axle.

4. The IC testing device as claimed in claim 1, wherein said axle is entirely formed of an elastic material, or only covered with an elastic material on its surface.

5. The IC testing device as claimed in claim 1, wherein said axle is made of a silicon elastomer, an elastomer fiber, a thermoplastic elastomer, or a synthetic elastomer.
